(19) United States
(12) Patent Application Publication
(10) Pub. No.: US 2010/0193950 A1
(43) Pub. Date: Aug. 5, 2010

(54) WAFER LEVEL, CHIP SCALE SEMICONDUCTOR DEVICE PACKAGING COMPOSITIONS, AND METHODS RELATING THERETO

(75) Inventors: YUEH-LING LEE, Raleigh, NC (US); BIN-HONG TSAI, Hsinchu (TW); JAMES CHU, Tapei (TW); CHENG-CHUNG CHEN, Raleigh, NC (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E.I.DU PONT DE NEMOURS AND COMPANY, Wilmington, DE (US)

(21) Appl. No.: 12/610,858

(22) Filed: Nov. 2, 2009

Related U.S. Application Data
(60) Provisional application No. 61/148,673, filed on Jan. 30, 2009.
(60) Provisional application No. 61/152,307, filed on Feb. 13, 2009.

(51) Int. Cl. H01L 23/48; H01L 21/768

(52) U.S. Cl. 257/738; 438/612; 257/773; 438/622; 257/E21.576; 257/E23.011; 257/E23.023

(57) ABSTRACT

The invention relates generally to wafer level, chip scale semiconductor device packaging compositions capable of providing high density, small scale circuitry lines without the use of photolithography. The wafer level package comprises a stress buffer layer containing a polymer binder and a spinel crystal filler in both a non-activated and a laser activated form. The stress buffer layer is patterned with a laser to thereby activate the filler, and the laser ablation path can then be selectively metalized.

### FIELD OF THE INVENTION

The present disclosure relates generally to wafer level, chip scale semiconductor device packaging compositions capable of providing high density, small scale circuitry lines without the use of photolithography. More specifically, the semiconductor device packaging of the present disclosure includes a high performance, laser activatable (and laser patternable) substrate that can enable higher I/O interconnects, and improved manufacturing cost, simplicity and reliability.

### DESCRIPTION OF THE RELATED ART

Broadly speaking, wafer level, chip scale packaging is known (see, for example, U.S. Pat. No. 6,368,896 to Farnworth, et al). Typically, metal circuitry is incorporated into such packaging, using photolithography. However, such photolithography is becoming increasingly challenging as the industry increasingly demands more complex packaging configurations involving higher density circuitry of finer and finer dimensions.

### SUMMARY OF THE INVENTION

The present disclosure is directed to a wafer-level chip packaging composition. The packaging composition comprises a stress buffer layer. The stress buffer layer comprises a polymer binder and a spinel crystal filler. The spinel crystal filler is in both a non-activated and a laser activate form. The polymer binder comprising 40 to 97 weight percent of the stress buffer layer. The polymer binder can be selected from:

polyimides,

benzocyclobutene polymer

polybenzoxazole

epoxy resins,

silica filled epoxy,

bismaleimide resins,

bismaleimide triazines,

fluoropolymers,

polyesters,

polyphenylene oxide/polyphenylene ether resins,

polybutadiene/polyisoprene crosslinkable resins (and copolymers thereof), liquid crystal polymers,

polyamides,

cyanate esters,

copolymers of any of the above, and

combinations of any of the above,

The spinel crystal filler comprises 3 to 60 weight-percent of the stress buffer layer. The spinel crystal filler in non-activated form is further defined by a chemical formula of AB₂O₄ and BABO₄, where A is a metal cation having a valence of 2 and is selected from a group consisting of copper, cobalt, tin, nickel, and combinations of two or more of these, and B is a metal cation having a valence of 3 and is selected from a group consisting of cadmium, manganese, nickel, zinc, copper, cobalt, magnesium, tin, titanium, iron, aluminum, chromium, and combinations of two or more of these.

The laser activated spinel crystal filler provides an electrical connection to a metallic pathway, at least a portion of the metallic pathway has an electrical connection to both a semiconductor device bonding pad and to a solder ball.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and together with the description, serve to explain the principles of the invention. In the drawings:

FIG. 1 is a cross-sectional view schematically illustrating a series of steps involving a laser activatable (laser patternable) stress buffer layer formed upon a wafer in the creation of a wafer-level package according to an embodiment of the present disclosure;

FIG. 2 is a cross-sectional view schematically illustrating a series of steps involving a laser activatable (laser patternable) stress buffer layer and a laser activatable (laser patternable) redistribution layer formed upon a wafer in the creation of a wafer-level package according to an embodiment of the present disclosure; and

FIG. 3 is a cross-sectional view schematically illustrating a series of steps involving a conventional stress buffer layer and a laser activatable (laser patternable) redistribution layer formed upon a wafer in the creation of a wafer-level package according to an embodiment of the present disclosure.

### BRIEF DESCRIPTION OF PREFERRED EMBODIMENTS

The following detailed description of the embodiments and examples of the present invention with reference to the accompanying drawings is intended to only be illustrative and not limiting.

### Definitions:

Unless otherwise defined, all technical and scientific terms used herein have the same meaning as commonly understood by one of ordinary skill in the art to which this invention belongs. Although methods and materials similar or equivalent to those described herein can generally be used in the practice or testing of the invention, suitable methods and materials are described below.

### Descriptions:

The wafer-level packaging of the present invention include one or more light-activatable, laser patternable materials, typically a film, layer or substrate. The light activatable, laser patternable material of the present disclosure comprises a polymer binder selected from:

polyimides,

benzocyclobutene polymer (“BCB”)

polybenzoxazole (“PBO”)

epoxy resins,

silica filled epoxy,

bismaleimide resins,

bismaleimide triazines,

fluoropolymers,

polyesters,

polyphenylene oxide/polyphenylene ether resins,

polybutadiene/polyisoprene crosslinkable resins (and copolymers thereof), liquid crystal polymers,

polyamides,

cyanate esters,

copolymers of any of the above, and

combinations of any of the above.

The polymer binder is present in an amount between (and optionally including) any two of the following percentages: 40, 45, 50, 55, 60, 65, 70, 75, 80, 85, 90, 95, 96 or 97 weight-percent, based upon the total weight of the light activatable substrate.

In addition to the binder polymer, the laser activatable (laser patternable) material also comprises a spinel crystal filler. The spinel crystal filler is present in an amount between (and optionally including) any two of the following percentages: 3, 4, 5, 6, 7, 8, 9, 10, 11, 12, 13, 14, 15, 20, 25, 30, 35, 40, 45, 50, 55 and 60 weight-percent, based upon the total weight of the light activatable substrate. Furthermore, the average particle size of the spinel crystal filler is between (and optionally including) any two of the following sizes 50, 100, 300, 500, 800, 1000, 2000, 3000, 4000, 5000 and 10000 nanometers.

The light-activatable (laser patternable) composition of the present disclosure can be manufactured according to a process comprising the steps of:
1. dispersing the spinel crystal filler in an organic solvent to form a dispersion,
2. combining the dispersion with the polymer binder or a precursor thereto, and
3. removing 80, 90, 95, 96, 97, 98, 99, 99.5 or more weight percent of the organic solvent

The light activatable (laser patternable) materials of the present disclosure can be light-activated with a laser beam. The laser beam can be used to ablate a pattern onto a surface of the light activatable material, and then a metal plating step can be performed, where metal will selectively build up at the laser activated ablation surface. Such metallization can be performed by an electroless (or optionally, electrolytic) plating bath to form electrically conductive pathways on the light activated pattern, and optionally also form metalized vias through the substrate.

In one embodiment, the light activatable (laser patternable) material has a visible-to-infrared light extinction coefficient between (and optionally including) any two of the following 0.05, 0.06, 0.07, 0.08, 0.09, 0.1, 0.2, 0.3, 0.4, 0.5, and 0.6 per micron.

The spinel crystal filler can have an average particle size between (and optionally including) any two of the following sizes: 50, 100, 300, 500, 800, 1000, 2000, 3000, 4000, 5000 and 10000 nanometers.

The laser activatable (laser patternable) compositions of the present disclosure may be impregnated into a glass structure to form a prepreg, may be impregnated into a fiber structure, or may be in the form of a film.

The film composites of the present invention may have a thickness between (and optionally including) any two of the following thicknesses: 1, 2, 3, 4, 5, 7, 8, 9, 10, 12, 14, 16, 18, 20, 25, 30, 35, 40, 45, 50, 55, 60, 65, 70, 75, 80, 85, 90, 95, 100, 125, 150, 175 and 200 microns.

The semiconductor device packaging of the present disclosure can additionally include (in addition to the laser activatable-laser patternable substrate) a functional layer. The functional layer can have any one of a number of functions, such as, a thermal conduction layer, a capacitor layer, a resistor layer, a dimensionally stable dielectric layer or an adhesive layer.

The laser activatable (laser patternable) compositions of the present disclosure may optionally further comprise an additive selected from the group consisting of an antioxidant, a light stabilizer, a light extinction coefficient modifier, a flame retardant additive, an anti-static agent, a heat stabilizer, a reinforcing agent, an ultraviolet light absorbing agent, an adhesion promoter, an inorganic filler (e.g., silica) a surfactant, a dispersing agent, or combinations thereof. Light extinction coefficient modifiers include, but are not limited to, carbon powder or graphite powder.

In one embodiment, the polymer compositions of the present disclosure have dispersed therein highly light activatable, spinel crystal fillers, where the fillers comprise two or more metal oxide cluster configurations within a definable crystal formation. The overall crystal formation, when in an ideal (i.e., non-contaminated, non-derivative) state, has the following general formula:

AB₂O₄

Where:
i. A (in one embodiment, A is a metal cation having primarily, if not exclusively, a valance of 2) is selected from a group including nickel, copper, cobalt, tin, and combinations thereof, which provides the primary cation component of a first metal oxide cluster (“metal oxide cluster 1”) typically a tetrahedral structure,
ii. B (in one embodiment, B is a metal cation having primarily, if not exclusively, a valance of 3) is selected from the group including chromium, iron, aluminum, nickel, manganese, tin, and combinations thereof and which provides the primary cation component of a second metal oxide cluster (“metal oxide cluster 2”) typically an octahedral structure,
iii. where within the above groups A or B, any metal cation having a possible valence of 2 can be used as an “A”, and any metal cation having a possible valence of 3 can be used as a “B”,
iv. where the geometric configuration of “metal oxide cluster 1” (typically a tetrahedral structure) is different from the geometric configuration of “metal oxide cluster 2” (typically an octahedral structure),
v. where a metal cation from A and B can be used as the metal cation of “metal oxide cluster 2” (typically the octahedral structure), as in the case of an ‘inverse’ spinel-type crystal structure,
vi. where O is primarily, if not exclusively, oxygen; and
vii. where the “metal oxide cluster 1” and “metal oxide cluster 2” together provide a singular identifiable crystal type structure having heightened susceptibility to electromagnetic radiation evidenced by the following property, when dispersed in a polymer-based dielectric at a loading of about 10 to about 30 weight percent, a “visible-to-infrared light” extinction coefficient can be measure to be between (and optionally including) any two of the following numbers, 0.05, 0.06, 0.07, 0.08, 0.09, 0.1, 0.2, 0.3, 0.4, 0.5 and 0.6 per micron.

The spinel crystal fillers can be dispersed in a polymer binder solution. The polymer binder solution includes polyimide and copolyimide polymers and resins, epoxy resins, silica filled epoxy, bismaleimide resins, bismaleimide triazines, fluoropolymers, polyesters, polyphenylene oxide/polyphenylene ether resins, polybutadiene/polyisoprene crosslinkable resins (and copolymers), liquid crystal polymers, polyamides, cyanate esters, or combinations thereof, dissolved in a solvent. The fillers are typically dispersed at a weight-percent between (and optionally including) any two of the following numbers 3, 5, 7, 9, 10, 12, 15, 20, 25, 30, 35, 40, 45, 50, 55 and 60 weight-percent of the polymer, and initially have an average particle size (after incorporation into the polymer binder) of between (and optionally including) any two of the following numbers 50, 100, 300, 500, 800, 1000, 2000, 3000, 4000, 5000 and 10000 nanometers.

The spinel crystal fillers can be dispersed in an organic solvent (either with or without the aid of a dispersing agent) and in a subsequent step, dispersed in a polymer binder solution to form a blended polymer composition. The blended polymer composition can then be cast onto a flat surface (or drum), heated, dried, and cured or semi-cured to form a polymer film with a spinel crystal filler dispersed therein.

The polymer film can then be processed through a light activation step by using a laser beam. The laser beam can be focused, using optical elements, and directed to a portion of the surface of the polymer film where a circuit-trace, or other electrical component, is desired to be disposed. Once selected portions of the surface are light-activated, the light-activated portions can be used as a path (or sometimes just a spot) for a circuit trace to be formed later, by a metal plating step, for example, an electroless plating step.

The number of processing steps employed to make a circuit using the polymer film or polymer composites of the present disclosure are often far fewer relative to the number of steps in the subtractive processes conventionally employed in the industry today.

In one embodiment, the polymer compositions and polymer composites have a visible-to-infrared (i.e., a wavelength range from 1 mm to 400 nm) light extinction coefficient of between (and optionally including) any two of the following numbers 0.05, 0.06, 0.07, 0.08, 0.09, 0.1, 0.2, 0.3, 0.4, 0.5, and 0.6 per micron (or 1/micron). Visible-to-infrared light is used to measure a light extinction coefficient for each film. The thickness of the film is used in the calculations for determining the light extinction coefficient.

As used herein, the visible-to-infrared light extinction coefficient (sometimes referred to herein to simply as ‘alpha’) is a calculated number. This calculated number is found by taking the ratio of measured intensity of a specific wavelength of light (using a spectrometer) after placing a sample of the composite film in a light beam path, and dividing that number by the light intensity of the same light through air.

If one takes the natural log of this ratio and multiplies it by (−1), then divides that number by the thickness of the film (measured in microns), a visible-to-infrared light extinction coefficient can be calculated.

The general equation for the visible-to-infrared light extinction coefficient is then represented by the general formula:

Alpha=−1×[In (I(X)/I(O))]/t

where I(X) represents the intensity of light transmitted through a film,

where I(O) represents the intensity of light transmitted through air, and

where t represents the thickness of a film.

Typically, the film thickness in these calculations is expressed in microns. Thus, the light extinction coefficient (or alpha number) for a particular film is expressed as 1/microns, or inverse microns (e.g., microns⁻¹). Particular wavelengths of light useful in the measurements discussed herein are typically those wavelengths of light covering the visible-to-infrared light portion of the spectrum.

In one embodiment, a light extinction coefficient modifier can be added as a partial substitute for some, but not all, of the spinel crystal filler. Appropriate amounts of substitution can range from, between (and optionally including) any two of the following percentages 1, 2, 3, 4, 5, 10, 15, 20, 25, 30, 35, or 40 weight percent of the total amount of spinel crystal filler component. In one embodiment, about 10 weight percent of the spinel crystal filler can be substituted with a carbon powder or graphite powder. The polymer composite formed therefrom should have a sufficient amount of spinel crystal structure present in the polymer composite to allow metal ions to plate effectively on the surface thereof, while the above mentioned amount of substitute (e.g., carbon powder) darkens the polymer composite sufficiently enough so that the a sufficient amount of light energy (i.e., an amount of light energy that effectively light activates the surface of the composite) can be absorbed.

A specific range of useful light extinction coefficients has been advantageously found for the polymer compositions and polymer composites. Specifically, it was found that the polymer compositions and polymer composites require a sufficient degree of light-absorption capability to work effectively in high-speed light activation steps typically employing the use of certain laser machines.

For example, in one type of light-activation step employed (e.g., a step employing the use of a laser beam) it was found that the polymer compositions and composites of the present invention are capable of absorbing a significant amount of light energy so that a well-defined circuit trace pattern can be formed thereon. This can be done in a relatively short time. Conversely, commercially available polymer films (i.e., films without these particular fillers, or films containing non-functional spinel crystal fillers) may take longer, have too low a light extinction coefficient, and may not be capable of light-activating in a relatively short period, if at all. Thus, many polymer films, even films containing relatively high loadings of other types of spinel crystal fillers, may be incapable of absorbing enough light energy to be useful in high-speed, light activation manufacturing, as well as being able to receive plating of a metal in well-defined circuit patterns.

Useful organic solvents for the preparation of the polymer binders of the invention should be capable of dissolving the polymer binders. A suitable solvent should also have a suitable boiling point, for example, below 225° C., so the polymer solution can be dried at moderate (i.e., more convenient and less costly) temperatures. A boiling point of less than 210, 205, 200, 195, 190, 180, 170, 160, 150, 140, 130, 120 or 110° C. is generally suitable.

The polymer binders of the present invention, when dissolved in a suitable solvent to form a polymer binder solution (and/or casting solution), may also contain one or more additives. These additives include, but are not limited to, processing aids, antioxidants, light stabilizers, light extinction coefficient modifiers, flame retardant additives, anti-static agents, heat stabilizers, ultraviolet light absorbing agents, inorganic fillers, for example, silicon oxides, adhesion promoters, reinforcing agents, and a surfactant or dispersing agent, and combinations thereof.

The polymer solution can be cast or applied onto a support, for example, an endless belt or rotating drum, to form a film layer. The solvent-containing film layer can be converted into a self-supporting film by baking at an appropriate temperature (which may be thermal curing) or simply by drying (or partial drying known as “B-stage”) which produces a substantially dry film. Substantially dry film, as used herein, is a defined as a film with less than 2, 1.5, 1.0, 0.5, 0.1, 0.05, or 0.01 weight-percent volatile (e.g., solvent or water) remaining in the polymer composite. In addition, thermoplastic polymer compositions, having the spinel crystal filler dispersed therein, can be extruded to form either a film or any other pre-determined shaped article.

In accordance with the invention, the polymer binder is chosen to provide important physical properties to the composition and polymer composite. Beneficial properties include, but are not limited to, good adhesiveness (i.e., metal adhesion or adhesion to a metal), high and/or low modulus (depending upon the application), high mechanical elongation, a low coefficient of humidity expansion (CHE), and high tensile strength.

As with the polymer binder, the spinel crystal filler can also be specifically selected to provide a polymer composite having a well-defined light-activated pathway after intense light-energy has been applied. For example, a well-defined light-activated pathway can more easily produce well-defined circuit metal traces after the light-activated material is submerged in an electroless-plating bath. Metal is typically deposited onto the light-activated portion of the surface of the polymer composite via an electroless-plating step.

In one embodiment, the polymer compositions of the invention are used to form a multi-layer (at least two or more layers) polymer composite. The multi-layer polymer composite can be used as at least a portion of a printed circuit board (“PCB”), chip scale package, wafer scale package, high density interconnect board (HDI), module, “LGA” Land grid array, “SOP” (System-on Package) Module, “QFN” Quad Flat package-No Leads, “FC-QFN” Flip Chip Quad Flat package-No leads, or other similar-type electronic substrate. Printed circuit boards (either covered with, or incorporating therein, the polymer composites) may be single sided, double sided, may be incorporated into a stack, or a cable (i.e. a flexible circuit cable). Stacks can include several individual circuits to form what is commonly referred to as a multi-layer board. Any of these types of circuits may be used in a solely flexible or rigid circuit or, or may be combined to form a rigid/flex or flex/rigid printed wiring board or cable.

In the case of a three-layer polymer composite, the spinel crystal filler can be in the outer layers, the inner layer, in at least two-layers, or in all three layers. In addition, the concentration (or loading) of the spinel crystal filler can be different or the same in each individual layer, depending on the final properties desired.

In one embodiment, electromagnetic radiation (i.e., light-energy via a laser beam) is applied to the surface of the polymer composite. In one embodiment, a polymer film or composite can be light activated using a commercially available, Esko-Graphics Cyrel® Digital Imager (CU). The imager can be operated in a continuous wave mode or can be operated in a pulse mode. The purpose of applying this energy, on a particular predetermined portion of the film, is to light-activate the film surface. As defined herein, the term light-activated is defined as a portion of a surface on a polymer composite, wherein a metal ion can bond to the surface in a manner capable of forming a metal circuit trace. If only a small amount of metal is electroless plated onto the light activated portion of a surface of the film, and is thereby rendered incapable of forming an electrically conductive pathway, the film may not be considered as ‘light-activatable’ for purposes herein.

A 50-watt Yttrium Aluminum Garnet (YAG) laser may be employed to light activate the polymer composites. However, other types of lasers can be used. In one embodiment, a YAG laser (e.g. Chicago Laser Systems Model CLS-960-S Resistor Trimmer System) can be used to emit energy between 1 and 100 watts, ranging at about 355, 532 or 1064 nm wavelengths light. Generally, the wavelength of the laser light useful to light-activate a portion of the surface of a polymer composite can range from a wavelength between and including any two of the following numbers 200 nm, 355 nm, 532 nm, 1064 nm, or 3000 nm.

Generally, a laser beam can be modulated using an acousto-optic modulator/splitter/attenuator device (AOM) and can produce up to 23 watts in a single beam. The polymer composites can be held in place by vacuum, or by adhesive (or both), on the outer surface of a drum or metal plate. A drum-type assembly can rotate the film at speeds ranging from 1 to 2000 revolutions per minute in order to reduce production time. Spot size (or beam diameter) of the laser beam can be at a focus distance of from between (and optionally including) any two of the following numbers, 1, 2, 4, 6, 8, 10, 15, 20 or 25 microns, typically 18 or 12 microns. Average exposures (e.g. energy dose) can be from between (and optionally including) any two of the following numbers 0.1, 0.5, 1.0, 2, 4, 6, 8, 10, 15 or 20 J/cm². In the examples, at least 4 and 8 J/cm² were used.

A digital pattern of a printed circuit board, known as an image file, can be used to direct light to desired portions (i.e., locations) on the surface of a polymer composite. Software may be used to store information regarding the location of lines, spaces, curves, pads, holes, and other information such as pad diameter, pad pitch, and hole diameter. This data may be stored in digital memory that is readily accessible to AOM electronic devices.

The movement of the laser light may be controlled by a computer and can be directed in an organized, predetermined, pixel-by-pixel (or line-by-line) manner across a panel or composite surface. The fine features, e.g., less than 100, 75, 50 or 25 microns in line width, of a circuit pattern are inscribed on a surface of the polymer composite. A combination of light sources, scanning, beam modulation, digital pattern transfer, and mechanical conditions stated above, may all be used to provide the desired particular circuit pattern.

In one embodiment, metal is subsequently applied to the light-activated portions of the polymer composites. For these polymer composites, metal can be plated onto a surface using an ‘electroless’ plating bath in an electroless-plating step. The plating baths may include a copper ion source, a reducing agent, an oxidizing agent, and a chelating agent, in addition to trace amounts of other additives.

Variables that can control the speed and quality in which a plating bath can plate metal onto a surface of a film include, but are not limited to the temperature of the plating bath, the amount of surface to be plated, the chemical balance of the solution (e.g., replenishing the plating solution with a substance that has been consumed), and the degree of mechanical agitation. The temperature range of a plating bath can be controlled at a temperature between room temperature and about 70 to 80° C. The temperature can be adjusted according to the type, and amount, of chelating agent (and other additives) used.

Digitally imaged circuits can be electroless copper plated by using a single-step or two-step process. First, the polymer compositions or composites of the present invention are digitally imaged by a light activation step. Light activation debris, or miscellaneous particles, can be removed by mechanical brushing, air or ultra-sonification in order for a clean electroless copper-plating step to begin. After these initial steps have been taken, the light-activated polymer compositions or composites can be submerged into an electroless copper-plating bath at a plating rate of approximately >3 microns/hour.

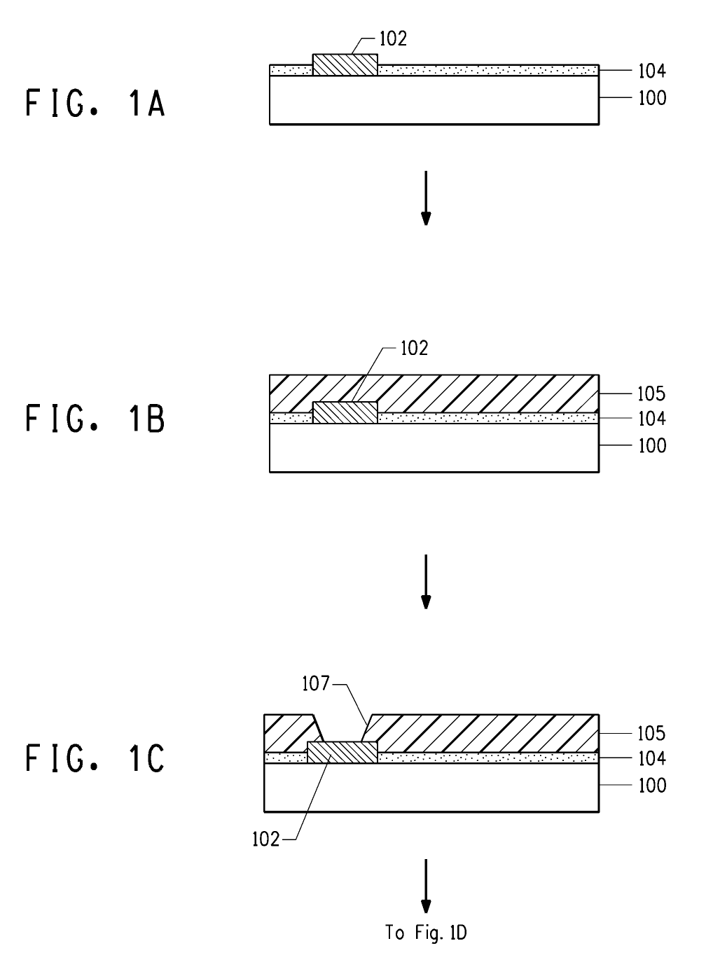

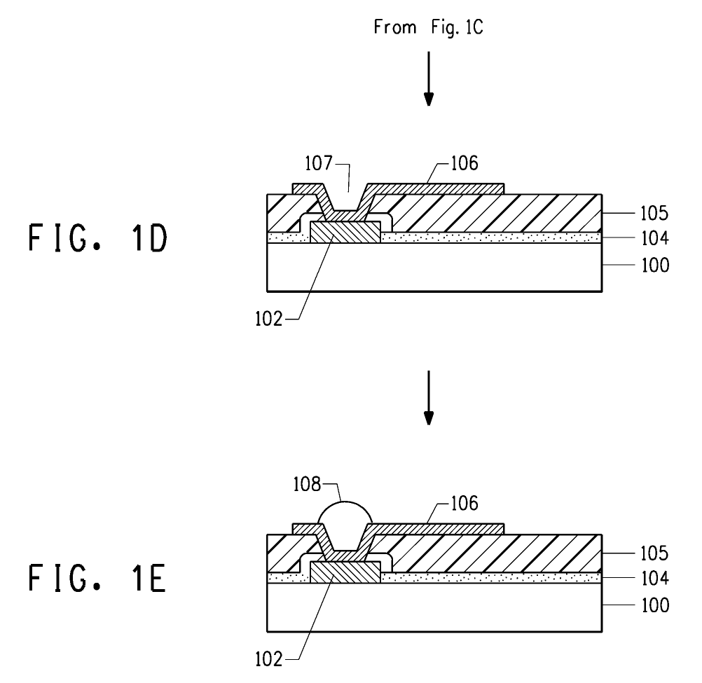

Referring now to FIG. 1 through FIG. 3, various cross-sectional views schematically illustrate various stages in a wafer-level packaging according to embodiments of the present invention.

With reference to FIG. 1, step 1 illustrates a wafer 100 with a plurality of bonding pads 102 thereon. Bonding pads 102 comprise a conductive metal, typically aluminum. A die passivation layer 104 is present, typically comprising silicon nitride. As illustrated at step 2 (of FIG. 1), a stress buffer layer 105 is laminated over the die passivation layer. The stress buffer layer 105 comprises the laser activatable (laser patternable) composition of the present disclosure. As illustrated at step 3 (of FIG. 1) the stress buffer layer 105 is laser ablated to provide an opening 107, exposing bonding pad 102.

As illustrated in step 4 (of FIG. 1), a metallization step is then conducted to provide an under bump metal (UBM) 106, creating an under bump metal coating 106 onto the pad 102 and optionally extending up and over opening 107 and optionally also extending along a portion of the stress buffer layer 105.

As illustrated in step 5 (of FIG. 1), a solder ball 108 is then applied into opening 107, electrically connecting the solder ball 108 to the under bump metal 106 which in turn is electrically connected to the pad 102.

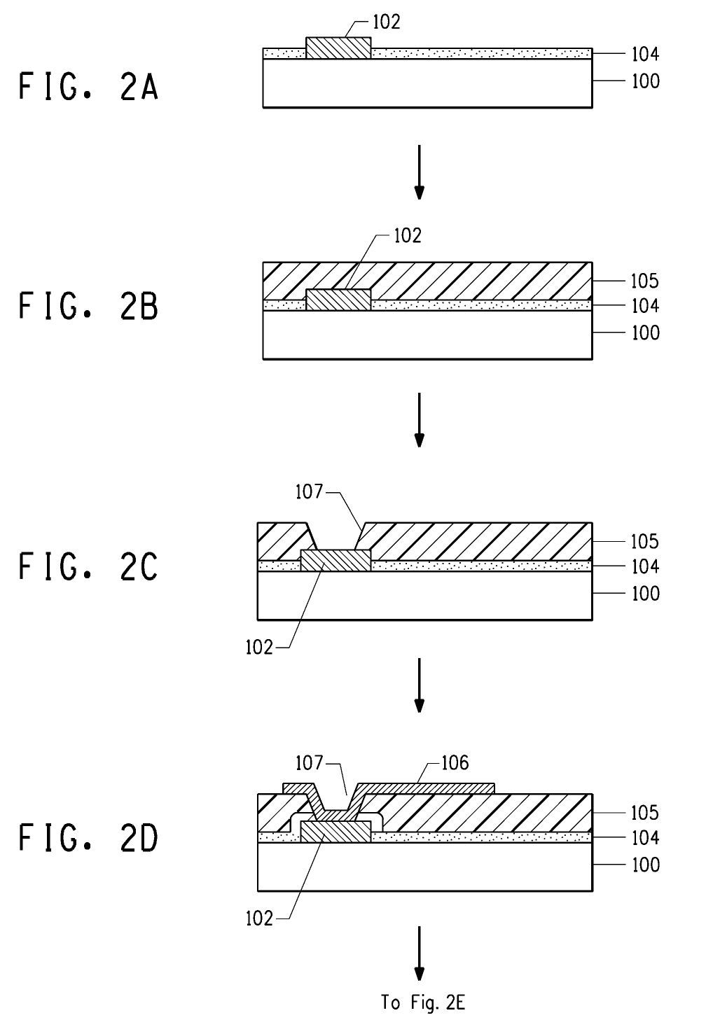

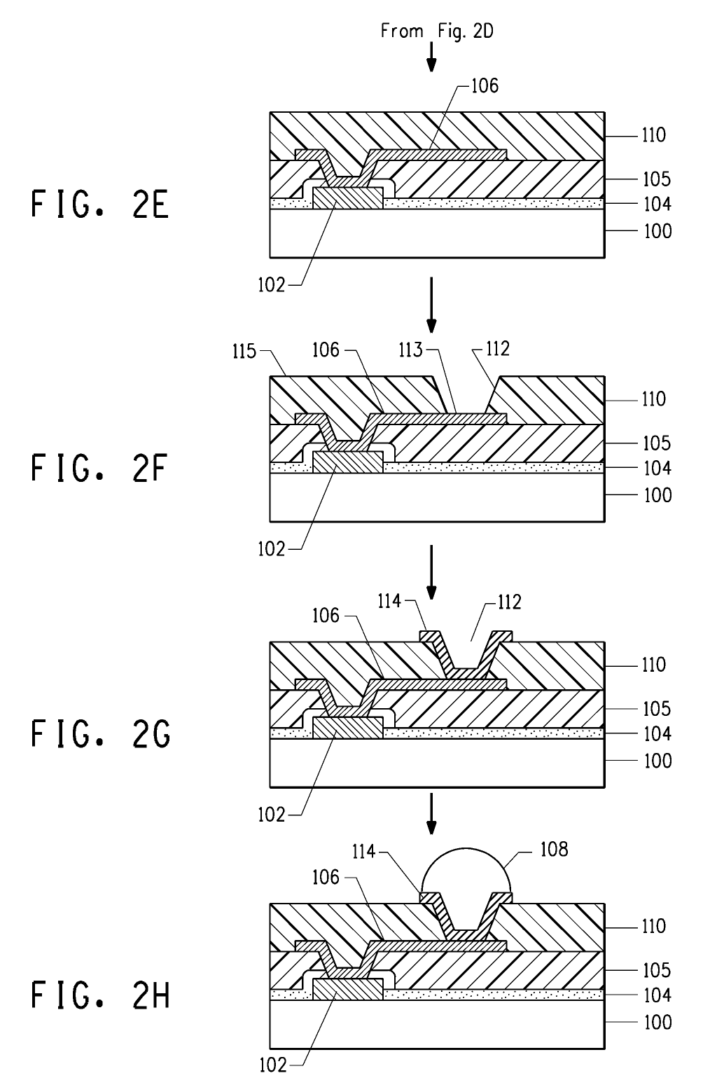

Next referring to FIG. 2, step 1 illustrates a wafer 100 comprising an aluminum pad 102 and a wafer passivation layer 104. Referring then to step 2 (of FIG. 2), a stress buffer layer 105 is applied over the wafer passivation layer 104. The stress buffer layer 105 comprises the laser activatable (laser patternable) composition of the present disclosure. As illustrated at step 3 (of FIG. 2) the stress buffer layer 105 is laser ablated to provide an opening 107, exposing bonding pad 102.

As illustrated in step 4 (of FIG. 2), a metallization step is then conducted to provide an under bump metal (UBM) 106, creating an under bump metal coating 106 onto the pad 102 and optionally extending up and over opening 107 and optionally also extending along a portion of the stress buffer layer 105 upper surface.

As illustrated in step 5 (of FIG. 2), a distribution layer 110 is then laminated over the under bump metal 106 and stress buffer layer 105. The distribution layer 110 also comprises the laser activatable (laser patternable) composition of the present disclosure and can be the same or different from the laser activatable (laser patternable) composition of the stress buffer layer 105.

As illustrated at step 6 (of FIG. 2) the distribution layer 110 is then laser ablated to provide an opening 112, exposing a portion 113 of the under bump metallization that extends from the bonding pad 102 to a surface portion of the stress buffer layer 105. The laser ablation activates the surface of opening 112, so metal will preferentially; if not exclusively, build up from the activated surface (in contradistinction to the non-activated portions 115, which will resist metallization).

As illustrated at step 7 (of FIG. 2) a metallization step is then conducted to provide a second under bump metal (UBM) coating 114 within opening 112.

As illustrated at step 8 (of FIG. 2) a solder bump is deposited onto (and is thereby electrically connected to) the second under metal bump coating 114, which in turn is electrically connected to the first under bump metallization 106, which in turn is connected to wafer bond pad 102.

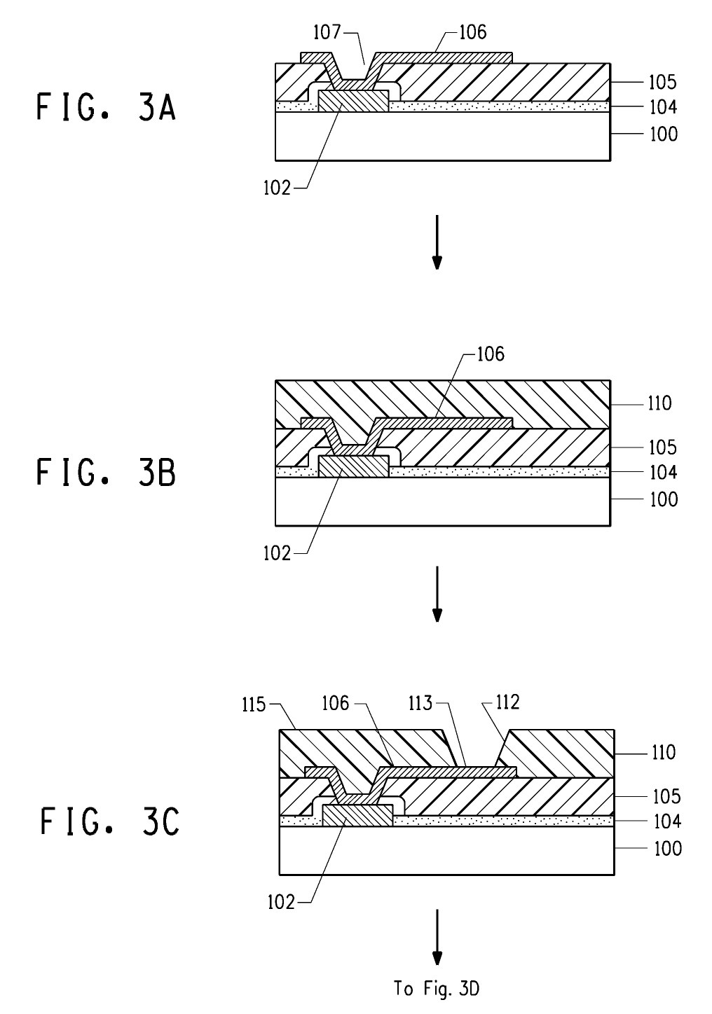

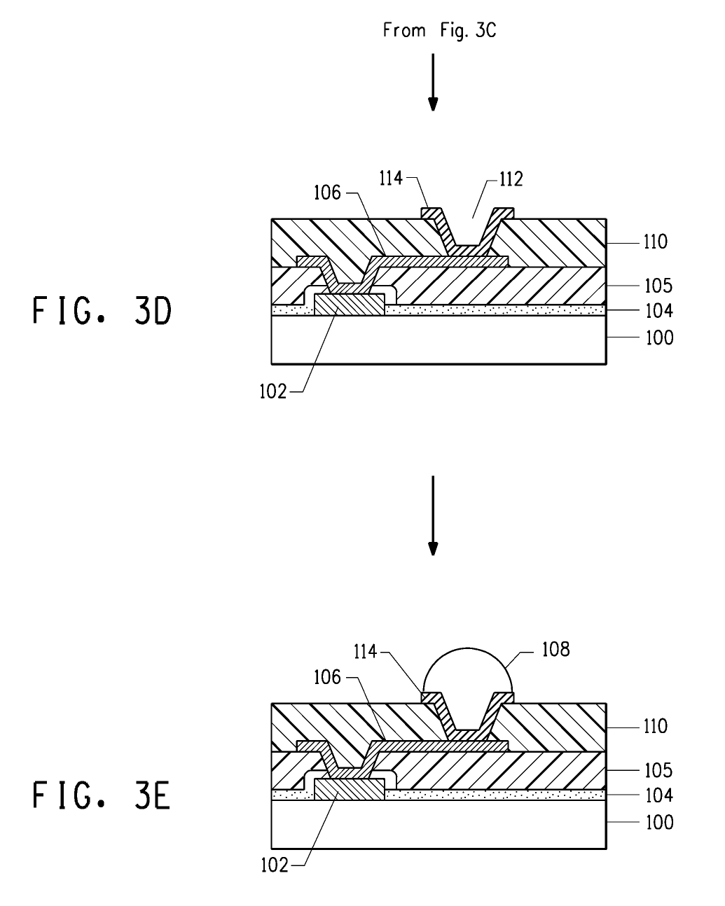

With reference to FIG. 3, step 1 illustrates a wafer 100 with a plurality of bonding pads 102 thereon. Bonding pads 102 comprise a conductive metal, typically aluminum. A die passivation layer 104 is present, typically comprising silicon nitride. A conventional stress buffer layer 105 of polyimide or benzocyclobutene polymer (“BOB”) is located over the die passivation layer 104. The stress buffer layer 105 comprises an opening 107, which is metalized with an under bump metallization layer 106.

As illustrated in step 2 (of FIG. 3), a distribution layer 110 is then laminated over the under bump metal 106 and stress buffer layer 105. The distribution layer 110 also comprises the laser activatable (laser patternable) composition of the present disclosure and can be the same or different from the laser activatable (laser patternable) composition of the stress buffer layer 105.

As illustrated in step 3 (of FIG. 3), the distribution layer 110 is then laser ablated to provide an opening 112, exposing a portion 113 of the first under bump metallization that extends from the bonding pad 102 to a surface portion of the stress buffer layer 110. The laser ablation activates the surface of opening 112, so metal will preferentially; if not exclusively, build up from the activated surface (in contradistinction to the non-activated portions 110, which will resist metallization).

As illustrated in step 4 (of FIG. 3) a metallization step is then conducted to provide a second under bump metal (UBM) 114 electrically connected to the first under bump metal coating 106 and optionally extending up and over opening 112 and optionally also extending along a portion of the stress buffer layer 110.

As illustrated in step 5 (of FIG. 1), a solder ball 108 is then applied into opening 112, electrically connecting the solder ball 108 to the second under bump metal 114 which in turn is electrically connected to the first under bump metal layer 106, which in turn is electrically connected to pad 102.

The laser activatable (laser patternable) substrates of the present disclosure can increase the number of input/output signal paths of a semiconductor package, due to the ease of using a laser to image and pattern, relative to conventional methods for creating input/output signal paths for semiconductor packaging. The laser activatable (laser patternable) substrates of the present disclosure also simplify packaging fabrication by eliminating the need for photolithography, including the need for photoresist, photo-development, etc. Under bump metallurgy (UBM) and re-distribution trace (RDL) for the external electrical connection can be formed (via electroless metal plating) after the laser patterning of the laser activatable (laser patternable) substrate is completed.

The stress buffer layer and/or redistribution layer can be applied in any one of a number of ways, such as, by lamination or spin-on coating, depending upon the viscosity and desired thickness of the layer.

It will be apparent to those skilled in the art that various modifications and variations can be made to the structure of the present invention without departing from the scope or spirit of the invention.

What is claimed is:

1. A wafer-level chip packaging composition comprising:
a stress buffer layer, the stress buffer layer comprising a polymer binder and a spinel crystal filler, the spinel crystal filler being in both a non-activated and a laser activate form, the polymer binder comprising 40 to 97 weight percent of the stress buffer layer, the polymer binder being selected from a group consisting of:
polyimides,
benzocyclobutene polymer
polybenzoxazole
epoxy resins,
silica filled epoxy,
bismaleimide resins,
bismaleimide triazines,
fluoropolymers,
polyesters,
polyphenylene oxide/polyphenylene ether resins,
polybutadiene/polyisoprene crosslinkable resins (and copolymers thereof), liquid crystal polymers,
polyamides,
cyanate esters,
copolymers of any of the above, and
combinations of any of the above,
the spinel crystal filler comprising 3 to 60 weight-percent of the stress buffer layer, the spinel crystal filler in non-activated form being further defined by a chemical formula of AB₂O₄ and BABO₄, where A is a metal cation having a valence of 2 and is selected from a group consisting of copper, cobalt, tin, nickel, and combinations of two or more of these, and B is a metal cation having a valence of 3 and is selected from a group consisting of cadmium, manganese, nickel, zinc, copper, cobalt, magnesium, tin, titanium, iron, aluminum, chromium, and combinations of two or more of these,
the laser activated spinel crystal filler having an electrical connection to a metallic pathway, at least a portion of the metallic pathway having an electrical connection to both a semiconductor device bonding pad and also to a solder ball.

2. A wafer-level package according to claim 1, further comprising a redistribution layer above the stress buffer layer, the redistribution layer comprising a laser-activated and non-activated spinel crystal filler and a polymer binder, the spinel crystal filler and the polymer binder of the redistribution layer being the same or different than the spinel crystal filler and the polymer binder of the stress buffer layer, wherein the distance between the bonding pad and the solder ball is greater than two millimeters.

3. A method of manufacturing a wafer-level chip packaging composition comprising:
providing a wafer comprising a top surface having a plurality of bonding pads,
placing a stress buffer layer over the bonding pad and the top surface of the wafer, the stress buffer layer comprising a polymer binder, the polymer binder being 40 to 97 weight percent of the stress buffer layer, the polymer binder being selected from:
polyimides,
benzocyclobutene polymer
polybenzoxazole
epoxy resins,
silica filled epoxy,
bismaleimide resins,
bismaleimide triazines,
fluoropolymers,
polyesters,
polyphenylene oxide/polyphenylene ether resins,
polybutadiene/polyisoprene crosslinkable resins (and copolymers thereof), liquid crystal polymers,
polyamides,
cyanate esters,
copolymers of any of the above, and
combinations of any of the above,
the stress buffer layer further comprising a spinel crystal filler, the spinel crystal filler comprising 3 to 60 weight-percent of the stress buffer layer, the spinel crystal filler having the chemical formula AB₂O₄ or BABO₄, where A is a metal cation having a valence of 2 and is selected from the group consisting of copper, cobalt, tin, nickel, and combinations of two or more of these, and B is a metal cation having a valence of 3 and is selected from the group consisting of cadmium, manganese, nickel, zinc, copper, cobalt, magnesium, tin, titanium, iron, aluminum, chromium, and combinations of two or more of these,
ablating the stress buffer layer with a laser beam to expose at least one bonding pad, said laser beam ablation creating an ablation surface, said ablation surface being activated by the laser beam, and metalizing at least a portion of the stress buffer layer ablation surface.

4. A method according to claim 3 further comprising:
applying a redistribution layer over the stress buffer layer,
the redistribution layer comprising a laser-activated and a non-activated spinel crystal filler and a polymer binder, the spinel crystal filler and the polymer binder of the redistribution layer being the same or different than the spinel crystal filler and the polymer binder of the stress buffer layer,
ablating the redistribution layer with a laser beam to expose at least one bonding pad, said laser beam ablation creating an ablation surface, said ablation surface being activated by the laser beam, and
metalizing at least a portion of the redistribution layer ablation surface.
